(19) United States
(12) Patent Application Publication
(10) Pub. No.: US 2007/0178618 A1
(43) Pub. Date: Aug. 2, 2007

(54) Method for manufacturing liquid crystal display panel

(75) Inventors: Chia-Ling Lin, Padeh City (TW); Chiu-Jung Huang, Padeh City (TW); Cheng-Chung Hu, Padeh City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Chunghwa Picture Tubes, Ltd., Padeh City (TW)

(21) Appl. No.: 11/344,311

(22) Filed: Jan. 31, 2006

(51) Int. Cl. H01L 21/00

(52) U.S. Cl. 438/30

(57) ABSTRACT

A method for manufacturing a liquid crystal display (LCD) panel, comprising providing a first substrate and a second substrate, dripping a plurality of liquid crystal (LC) drops on the first substrate and the second substrate, wherein the plurality of LC drops form a LC drop area having at least a void area, assembling the first substrate and the second substrate in a first environment, and placing the first substrate and the second substrate in a second environment having a greater atmospheric pressure than that of the first environment. Since the method is based on improvement of the dripped LC drop pattern, spacing uniformity occurring with the cell gap and thus displaying non-uniformity and deficiencies such as a vertical flow LC may be considerably reduced.

### BACKGROUND OF THE INVENTION

1. Field of the Invention

The present invention relates to a method for manufacturing a liquid crystal display (LCD) panel and particularly to a method for manufacturing an LCD panel by filling liquid crystal (LC) into an LCD panel.

2. Descriptions of the Related Art

After the rapid development in the recent years, LCDs have gradually replaced cathode ray tubes (CRTs) as the mainstream displays. For the current LCD fabrication, a one drop fill process is generally utilized and manufacturing cost and production yield of the LCD may be decreased and increased, respectively. Referring to FIG. 1A, a top view of a first substrate of a conventional LCD is shown therein. FIG. 1B is a top view of a second substrate of the conventional LCD. When the one drop fill process is performed, a plurality of LC drops 12 are dripped on the first substrate 11 and form a LC drop area 13. On the second substrate 14, a panel periphery seal 15 and a substrate periphery seal 16 are coated. Referring to FIG. 1C, a top view of the first substrate and the second substrate of the conventional LCD when an alignment step is performed is shown therein. In performing the alignment operation, the first substrate 11 and the second substrate 14 are disposed in parallel in a vacuum so that the LC drop area 13 coincides with an area enclosed by the panel periphery seal 15. Referring to FIG. 1D, a top view of the first substrate and the second substrate of the conventional LCD when an assembly step is performed is shown therein. In performing this step, the first substrate 11 and the second substrate 14 are bonded together as an assembled substrate 17 by use of the panel periphery seal 15 and the substrate periphery seal 16. At this time, the LC drops 12 are compressed by the second substrate 14 and spread into a LC layer 18.

Referring to FIG. 1E, a cross sectional view taken along line D-D shown in FIG. 1D is depicted therein. To prevent the LC layer 18 from being polluted by the panel periphery seal 15, the LC layer 18 is maintained in a central region of the assembled substrate 17 before the panel periphery seal 15 is solidified in an atmospheric environment. In this regard, a spacing L1 at the central region of the assembled substrate 17 is made greater than a spacing L2 at two inner ends of the assembled substrate 17.

Referring to FIG. 1F, a structural diagram of an assembled substrate corresponding to the assembled substrate shown in FIG. 1E after a period of time is depicted therein. The LC layer 18 is spread uniformly in an interior region of the assembled substrate 17. With the effects of the atmospheric pressure and the spreading of the LC layer 18, the spacing L1 of the assembled substrate 17 at the central region decreases gradually. Referring to FIG. 1G, a structural diagram of an assembled substrate corresponding to the assembled substrate shown in FIG. 1F after a period of time is depicted therein. When the panel periphery seal 15 is solidified, the spacing L3 at the two outer sides is greater than the spacing L1 owing to the atmospheric pressure. Such non-uniform of cell gap at different portions of the panel generally leads to a non-uniform displaying, mura, and deficiencies such as a vertical LC flow.

Whether a uniform spacing be presented across an LCD panel may have a critical influence on if an LCD panel of high quality may be obtained. Therefore, how to prevent a non-uniform spacing from occurring with the cell gap in the one drop fill process and thus a non-uniform displaying and deficiencies such as a LC vertical flow is a critical issue in the LCD panel manufacturing filed.

### SUMMARY OF THE INVENTION

It is an object of the present invention to provide a technology through which a non-uniform spacing may be prevented from occurring with the cell gap in a one drop fill process and thus a non-uniform displaying and deficiencies such as a LC vertical flow may also be prevented so that an enhanced quality of the manufactured LCD may be achieved.

To achieve the above object, the present invention provides a method for manufacturing a LCD panel, comprising the steps of providing a first substrate and a second substrate, dripping a plurality of LC drops on the first substrate or the second substrate, wherein the plurality of LC drops form a LC drop area having at least a void area, assembling the first substrate and the second substrate in a first environment, and placing the first substrate and the second substrate in a second environment having a greater atmospheric pressure than that of the first environment.

With execution of the inventive method, based on improvement of the dripped LC drop pattern, the spacing non-uniformity occurring with the cell gap and thus the displaying non-uniformity and deficiencies such as a LC vertical flow may be considerably reduced.

To enable the above and other objects, features and advantages apparent to those skilled in the art, the present invention will be described in more detail taken from the preferred embodiments in conjunction with the appended drawings.

### BRIEF DESCRIPTION OF THE DRAWINGS

FIG. 1A shows a top view of the first substrate of a conventional LCD;

FIG. 1B shows a top view of the second substrate of a conventional LCD;

FIG. 1C show a top view of the first substrate and the second substrate of the conventional LCD when an alignment step is performed;

FIG. 1D shows a top view of the first substrate and the second substrate of the conventional LCD when an assembly step is performed;

FIG. 1E shows a cross sectional view taken along line D-D shown in FIG. 1D;

FIG. 1F shows a structural diagram of an assembled substrate corresponding to the assembled substrate shown in FIG. 1E after a period of time;

FIG. 1G shows a structural diagram of an assembled substrate corresponding to the assembled substrate shown in FIG. 1F after a period of time;

FIG. 2 shows a top view of a first substrate of an LCD panel according to the present invention;

FIG. 3 shows a top view of a second substrate of the LCD panel according to the present invention;

FIG. 4 shows a top view of the LCD panel when an alignment process is performed according to the present invention;

FIG. 5A shows a top view of the LCD panel when an alignment process is performed according to the present invention;

FIG. 5B shows a cross sectional view of the LCD panel taken along line A-A shown in FIG. 5A according to the present invention;

FIG. 6A shows a structural diagram of the LCD panel after the whole manufacturing process is performed according to the present invention;

FIG. 6B shows a cross sectional view of the LCD panel shown in FIG. 6A according to the present invention;

FIG. 6C shows a flowchart illustrating the method of manufacturing the LCD panel according to the present invention;

FIG. 7A shows a top view of the first substrate of the LCD panel according to another embodiment of the present invention;

FIG. 7B shows a top view of the second substrate of the LCD panel shown in FIG. 7A according to the another embodiment of the present invention;

FIG. 7C shows a top view of the LCD panel when an assembly process is performed shown in FIG. 7A according to another embodiment of the present invention; and

FIG. 7D shows an embodiment of the drop area in FIG. 7B further including a void area.

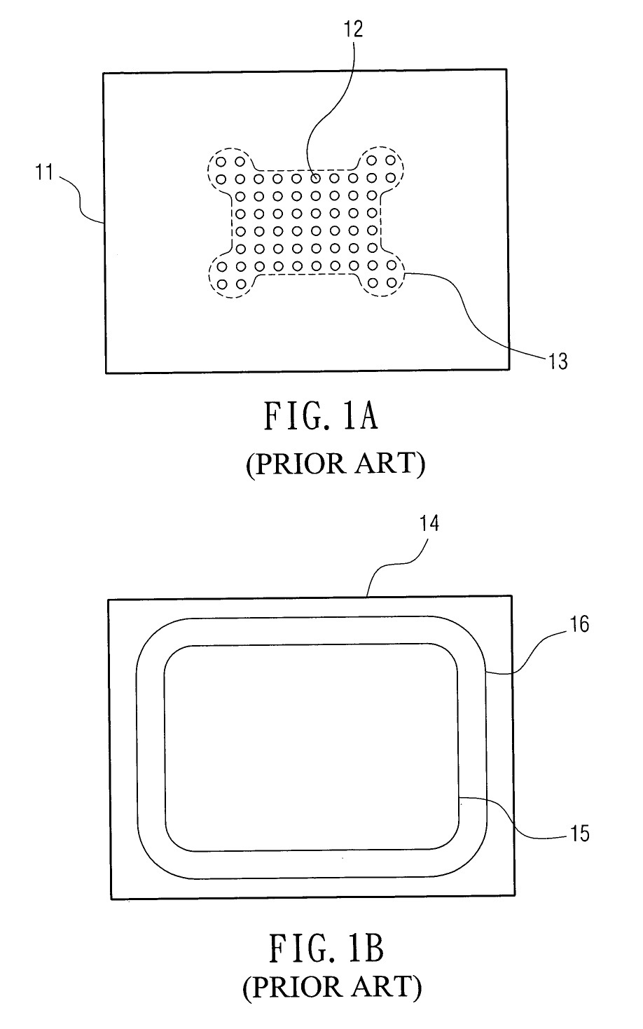

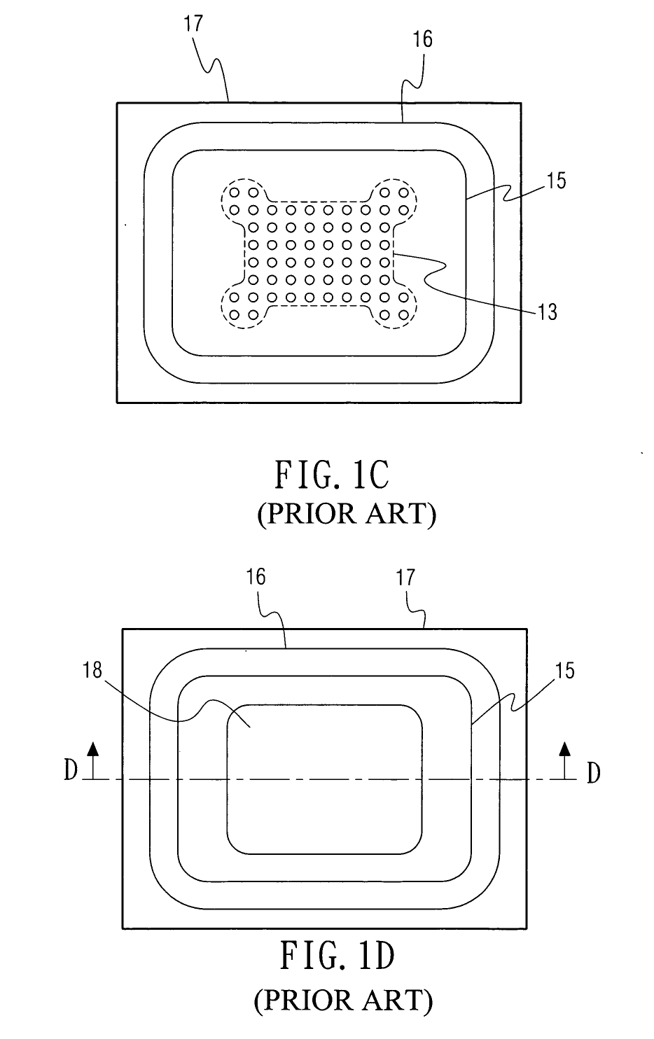

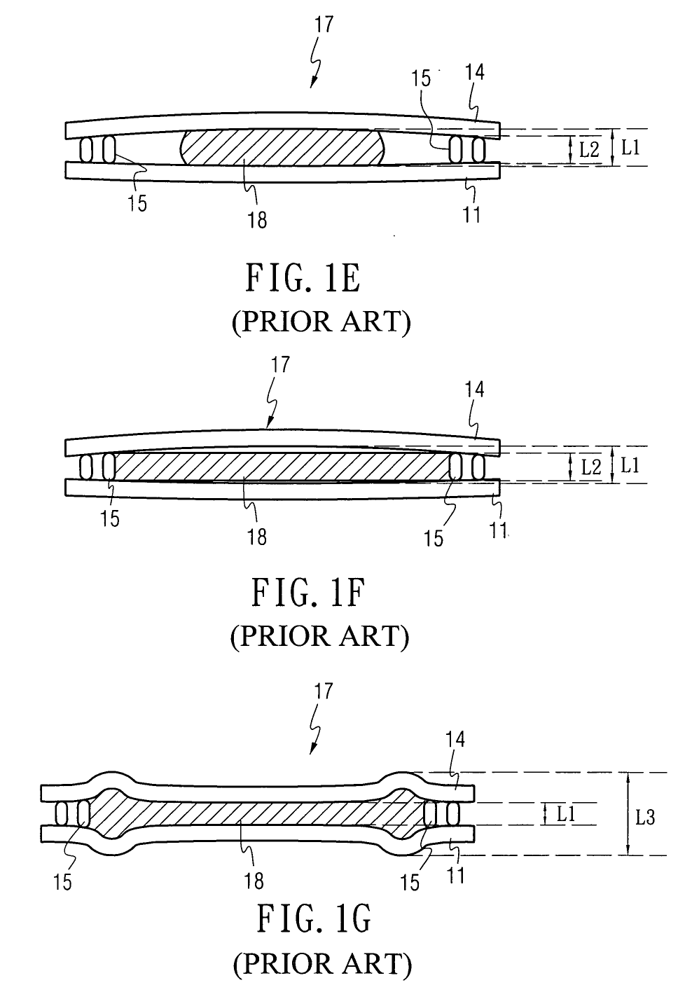

### DETAILED DESCRIPTION OF THE INVENTION

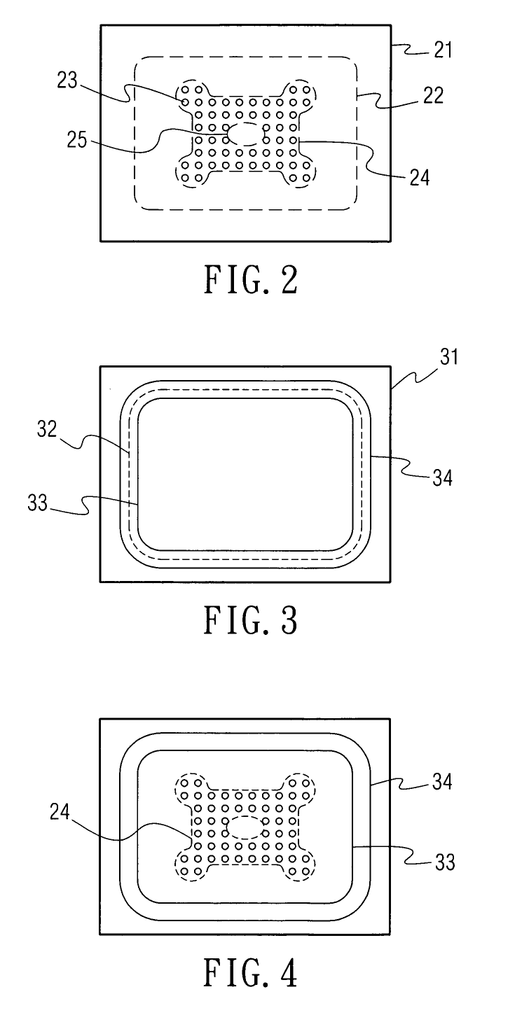

Referring to FIG. 2, a top view of a first substrate is shown therein. To facilitate the description, only a TFT array containing an LCD panel unit 22 is disposed on the first substrate 21. However, the first substrate 21 may include TFT arrays containing a plurality of LCD panel units 22. The first substrate 21, such as a TFT array, may be a glass substrate. A plurality of scan lines (now shown) are disposed in parallel and a plurality of data lines (not shown) are disposed in parallel and perpendicularly to the scan lines on the substrate 21. In the vicinity of crossing points of the plurality of the scan lines and the plurality of data lines, a plurality of TFTs (not shown) in a matrix form and transparent electrodes (not shown) are formed. Each of the transparent electrodes may be made of indium tin oxide (ITO) or indium zincoide (IZO). A plurality of LC drops 23 are dripped on the first substrate 21 and form a LC drop area 24. At least a void area 25 exists in the LC drop area 24 approximately at a central region thereof.

Referring FIG. 3, a top view of a second substrate of an LCD panel according to the present invention is shown therein. To facilitate the description, only a color filter containing an LCD panel unit 32 is disposed on the second substrate 31. However, the second substrate 31 may include color filters containing a plurality of LCD panel units 32. The second substrate 31, such as a color filter substrate, may be a glass substrate on which a plurality of color filters (now shown), a plurality of gaps (not shown) and a plurality of transparent electrodes (not shown) are disposed. The plurality of color filters and the plurality of gaps may be formed by photosensitive resins. In addition, at least a panel periphery seal 33 and a substrate periphery seal 34 are also formed on the second substrate 31. Each of the seals 33, 34 may be a seal solidifiable by ultraviolet. The substrate periphery seal 34 is coated on a peripheral region of the second substrate 31, while the panel periphery seal 33 is coated on a peripheral region of the LCD panel unit 32. In the case where the second substrate 31 has a plurality of LCD panel units 32, each of the plurality of LCD panel units 32 has to be coated with the panel periphery seal 33 at the peripheral region.

Referring to FIG. 4, a top view of the LCD panel when an alignment process is performed according to the present invention is shown therein. In performing this process, the first substrate 21 and the second substrate 31 are placed in parallel in a vacuum environment in such a manner that the LC drop area 24 coincides with an area enclosed by the panel periphery seal 33.

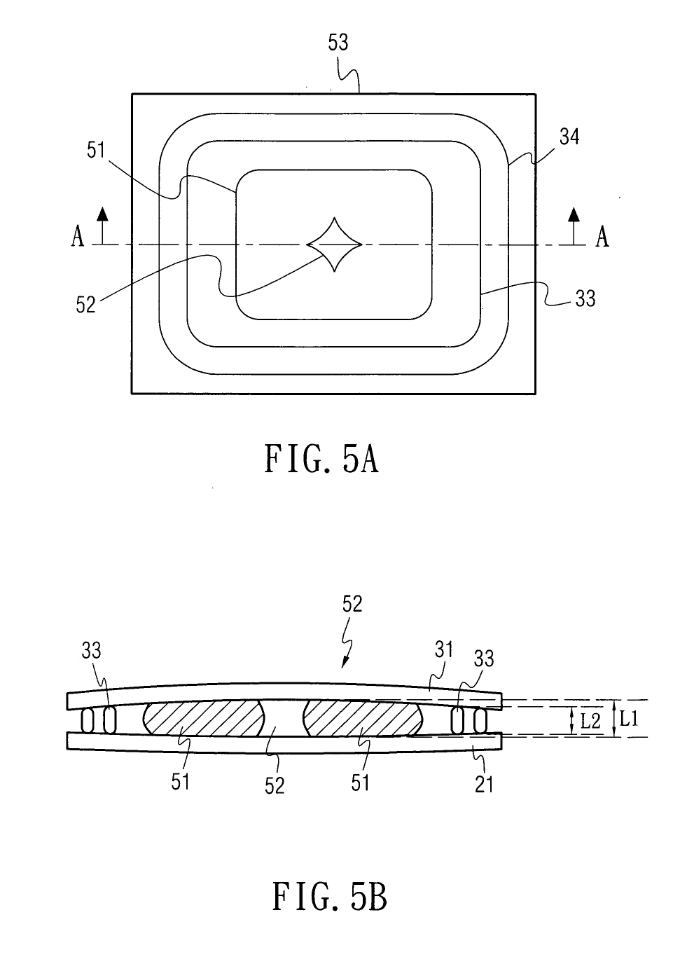

Referring to FIG. 5A, a top view of the LCD panel when an assembly process is performed according to the present invention is shown therein. In performing this process, the first substrate 21 and the second substrate 31 are bonded into an assembled substrate 53. At this time, the plurality of LC drops 23 in the LC drop area 24 is spread into a LC layer 51. The void area 25 is located approximately at a central region of the LC layer 51 and forms a negative pressure area 52. Thereafter, ultraviolet is used to solidify the panel periphery seals 33 and the substrate periphery seal 34 and the assembled substrate 53 is placed in an atmospheric environment. As such, the substrate periphery seal 34 may protect the panel periphery seal 33 from impact and thus damage resulted from the atmospheric pressure.

Referring to FIG. 5B, a cross sectional view taken along line A-A shown in FIG. 5A according to the present invention is depicted therein. The LC layer 51 is formed between the first substrate 21 and the second substrate 31 and isolated with the external environment by the panel periphery seal 33. The negative pressure area 52 is formed approximately at a central region of the LC layer 51. Since the first substrate 21 and the second substrate 31 are forced to each other due to the atmospheric pressure outside, the LC layer 51 is compressed. Further, the LC layer 51 is compressed by the first substrate 21 and the second substrate 31 and the negative area 52 also provides an attractive force. As such, the LC layer 51 is spread towards the central region and the two ends of the assemble substrate 53.

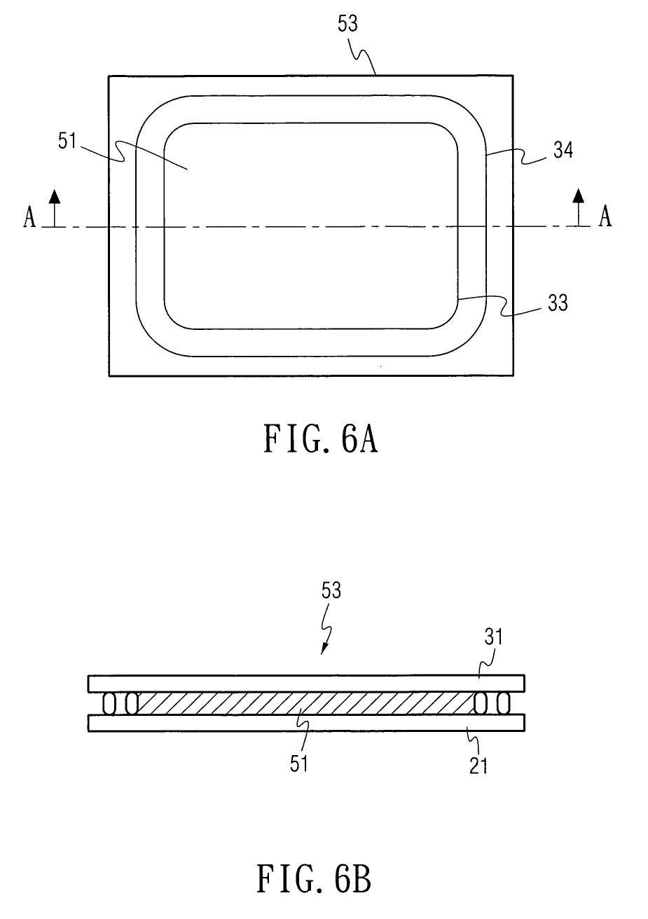

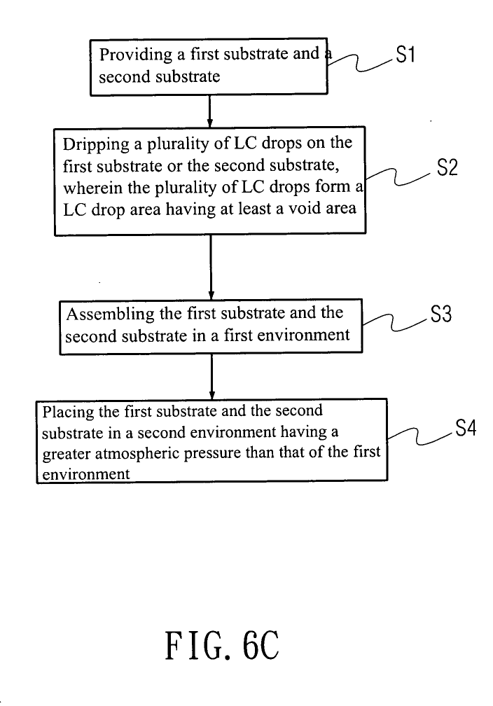

Referring to FIG. 6A, a structural diagram of the LCD panel after the whole manufacturing process is performed according to the present invention is shown therein. The area enclosed by the panel periphery seal 33 is fully filled by the LC layer 51. As such, the LC layer 51 is distributed uniformly within the area enclosed by the panel periphery seal 33.

Referring to FIG. 6B, a cross sectional view of the LCD panel shown in FIG. 6A according to the present invention is shown therein. With the existence of the negative pressure area 52, the LC layer 51 is spread towards the central region and the two ends of the assembled substrate 53 and thus the LC layer 51 is distributed uniformly. As such, spacing uniformity of the cell gap may be considerably improved and displaying non-uniformity and the vertical LC flow may be prevented.

Referring to FIG. 6C, a flowchart illustrating the method of manufacturing the LCD panel according to the present invention is shown therein. As shown, the method comprises the following steps. At first, providing a first substrate and a second substrate (S1), dripping a plurality of LC drops on the first substrate or the second substrate, wherein the plurality of LC drops form a LC drop area having at least a void area (S2), assembling the first substrate and the second substrate in a first environment (S3), and placing the first substrate and the second substrate in a second environment having a greater atmospheric pressure than that of the first environment (S4).

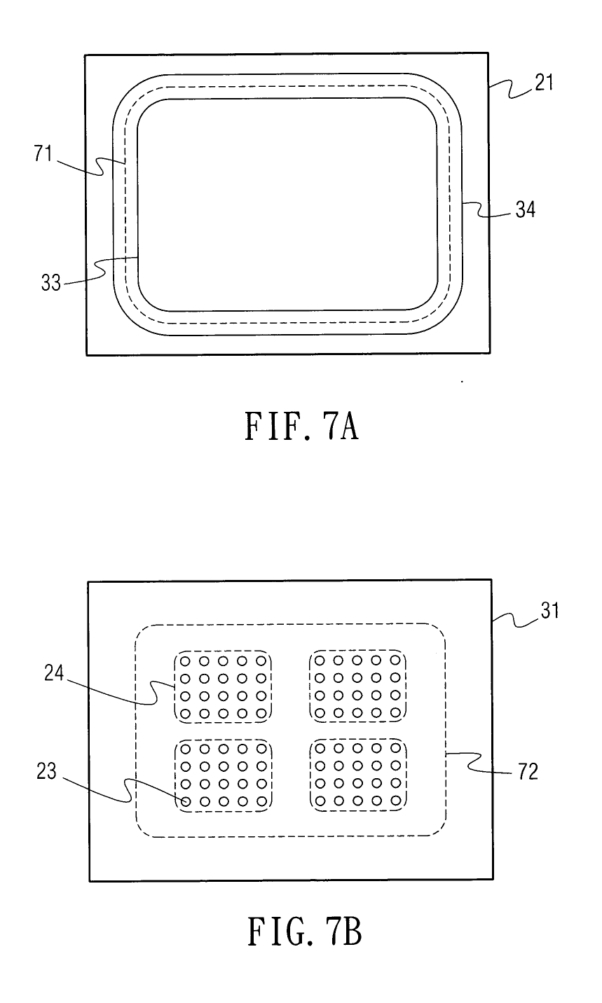

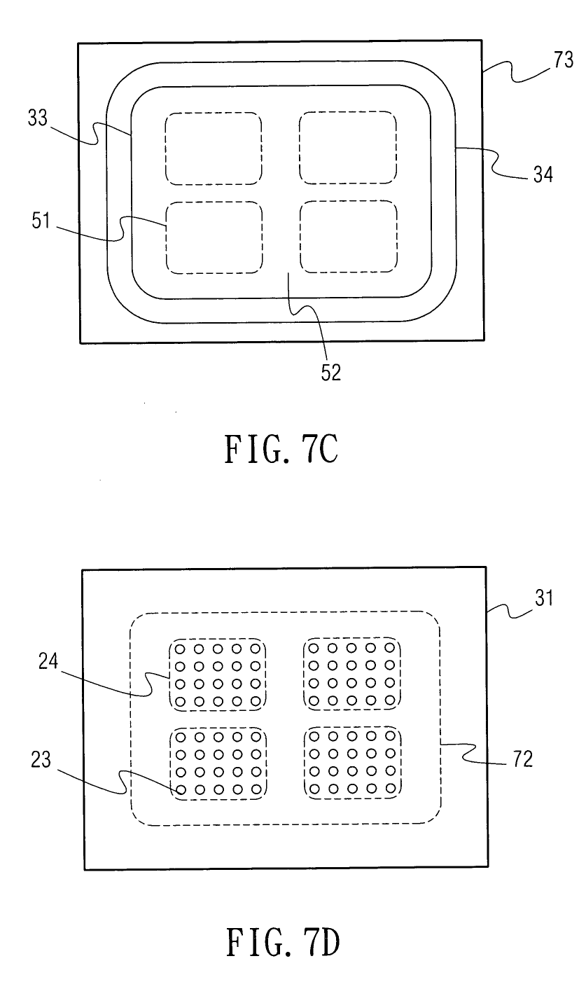

Referring to FIG. 7A, a top view of the first substrate of the LCD panel according to another embodiment of the present invention is shown therein. To facilitate the description, only a TFT array containing a liquid crystal display (LCD) panel unit 71 is arranged in the first substrate 21. However, the first substrate 21 may include TFT arrays containing a plurality of LCD panel units 71. On the first substrate 21, at least a panel periphery seal 33 and a substrate periphery seal 34 are coated. The seals 33, 34 may each be a seal solidifiable by ultraviolet. The substrate periphery seal 34 is coated on a peripheral region of the first substrate 21. In the case where the first substrate 21 has a plurality of LCD panel units 71, each of the plurality of LCD panel units 71 has to be coated with the panel periphery seal 33 in the peripheral region.

Referring to FIG. 7B, a top view of the second substrate of the LCD panel according to another embodiment of the present invention is shown therein. To facilitate the description, only a color filter containing an LCD panel unit 72 is arranged in the second substrate 31. However, the second substrate 31 may also include color filters containing a plurality of LCD panel units 72. On the second substrate 31, the plurality of LC drops 23 forms a plurality of LC drop areas 24.

Referring to FIG. 7C, a top view of the LCD panel when an assembly process is performed according to another embodiment of the present invention is shown therein. In performing this process, the first substrate 21 and the second substrate 31 are bonded into an assembled substrate 73. At this time, the plurality of LC drops 23 in the LC drop area 24 are spread into a LC layer 51 and a negative pressure area 52 is formed in the LC drop area 24. Thereafter, ultraviolet is used to solidify the panel periphery seals 33 and the substrate periphery seal 34 and the assembled substrate 73 is placed in an atmospheric environment. With the existence of the negative pressure area 52, the LC layer 51 is spread towards the central region and the two ends of the assembled substrate 73 and thus the LC layer 51 is distributed uniformly. As such, spacing uniformity of the cell gap may be considerably improved and displaying non-uniformity and a vertical LC flow may be prevented.

FIG. 7D shows an embodiment of the drop area 24 further including a void area 25. In FIG. 7D, the void area 25 is located on the central region of the drop area 24.

In conclusion, this invention, based on the improved pattern of the LC drops, may reduce considerably the spacing non-uniformity occurred with the cell gap and may prevent the LCD panel from the non-uniform displaying and deficiencies such as the vertical LC flow, compared with the prior art.

The above disclosure is intended as merely exemplary, and not to limit the scope of the invention—which, rather, is to be determined by reference to the appended claims. Hence, any modification and form derived or deduced from the present invention should be constructed as within the scope of the invention.

What is claimed is:

1. A method for manufacturing a liquid crystal display (LCD) panel, comprising the steps of:
providing a first substrate and a second substrate;
dripping a plurality of liquid crystal (LC) drops on said first substrate or said second substrate, wherein said plurality of LC drops form a LC drop area having at least a void area;
assembling said first substrate and said second substrate in a first environment, and
placing said first substrate and said second substrate in a second environment having a greater atmospheric pressure than that of said first environment.

2. The method according to claim 1, wherein said void area is located approximately at a central region.

3. The method according to claim 1, further comprising a step of aligning said first substrate and said second substrate in such a manner that said LC drop area coincides with an area enclosed by the panel periphery area.

4. The method according to claim 1, wherein the step of assembling said first substrate and said second substrate is achieved by bonding said first substrate and said second substrate with a seal.

5. The method according to claim 4, wherein said seal includes at least a panel periphery seal.

6. The method according to claim 5, wherein said seal further comprises a substrate periphery seal.

7. The method according to claim 4, further comprising a step of solidifying said seal.

8. The method according to claim 1, wherein said first substrate is a thin film transistor (TFT) substrate.

9. The method according to claim 1, wherein said second substrate is a color filter substrate.

10. A method for manufacturing an LCD panel, comprising the steps of:
providing a first substrate and a second substrate;
dripping a plurality of LC drops on said first substrate or said second substrate, wherein said plurality of LC drops form a LC drop area;
assembling said first substrate and said second substrate in a first environment, and
placing said first substrate and said second substrate in a second environment having a greater atmospheric pressure than that of said first environment.

11. The method according to claim 10, wherein each of said LC drop area has at least a void area therein.

12. The method according to claim 11, further comprising a step of aligning said first substrate and said second substrate in such a manner that said LC drop area coincides with an area enclosed by the panel periphery area.

13. The method according to claim 10, wherein the step of assembling said first substrate and said second substrate is achieved by bonding said first substrate and said second substrate with a seal.

14. The method according to claim 13 further comprising a step of solidifying said seal.

15. The method according to claim 13, wherein said seal includes at least a panel periphery seal.

16. The method according to claim 15, wherein said seal further comprises a substrate periphery seal.

17. The method according to claim 13, wherein said seal is a seal solidifiable by ultraviolet.

18. The method according to claim 10, wherein said first substrate is a thin film transistor substrate.

19. The method according to claim 10, wherein said second substrate is a color filter substrate.
